(19) United States
(12) Patent Application Publication
(10) Pub. No.: US 2025/0264902 A1
(43) Pub. Date: Aug. 21, 2025

(54) BIASING DEVICE FOR VARIABLE CAPACITANCE

(71) Applicant: STMicroelectronics International N.V., Geneva (CH)

(72) Inventors: Olivier TOUZARD, Grenoble (FR); Eric ANDRE, HURTIERES (FR)

(21) Appl. No.: 19/047,239

(22) Filed: Feb. 6, 2025

(30) Foreign Application Priority Data
Feb. 20, 2024 (FR) FR2401637

(51) Int. Cl. G05F 3/26; H03L 7/099

(52) U.S. Cl. CPC G05F 3/267; H03L 7/099

(57) ABSTRACT

A biasing device for variable capacitance is provided. An example device comprises a first circuit. The first circuit delivers a first current flowing through a first resistive element receiving a temperature-stable voltage, and a second current proportional to temperature. A second resistive element comprises MOS transistors in series and connected as a diode, and has a first terminal connected to a reference potential and a second terminal coupled to a power supply potential. A second circuit delivers, in the second resistive element, a copy of the first current. A third circuit applies a voltage to a back gate of the transistors, determined by the second current.

### CROSS REFERENCE TO RELATED APPLICATIONS

This application claims the priority benefit of French patent application number 2401637, filed on Feb. 20, 2024, entitled “Dispositif de Polarisation d′une Capacité Variable,” which is hereby incorporated by reference to the maximum extent allowable by law.

### TECHNICAL FIELD

The present disclosure generally concerns electronic circuits, and more particularly electronic circuits comprising a variable capacitor.

### BACKGROUND

Many electronic circuits comprise a variable capacitor, that is, a capacitive component having an adjustable capacitance value. As an example, voltage-controlled oscillators are electronic circuits comprising a variable capacitor.

Electronic circuits comprising a variable capacitor have various disadvantages. For example, their operation may depend on temperature in addition to the value of their variable capacitance, which poses a problem. This is for example the case in voltage-controlled oscillators comprising a variable capacitor, such as voltage-controlled oscillators configured to deliver a radio frequency signal having, for example, a frequency greater than 1 GHz, or even greater than 10 GHz, for example approximately equal to 20 GHZ.

### BRIEF SUMMARY

There exists a need to overcome all or part of the disadvantages of electronic circuits comprising a variable capacitor.

For example, there is a need for a device delivering a voltage to a variable capacitor of an electronic circuit, which enables to at least partly compensate for the effect of temperature on an operating parameter of the electronic circuit.

For example, there exists a need for a device enabling to deliver a voltage to a variable capacitor of a voltage-controlled oscillator which enables to at least partially compensate for the effect of temperature on the oscillator frequency, for example when the oscillator frequency is controlled by a phase-locked loop (PLL).

An embodiment overcomes all or part of the disadvantages of known electronic circuits comprising a variable capacitor.

For example, an embodiment overcomes all or part of the disadvantages of known devices delivering a voltage to a variable capacitor of an electronic circuit.

For example, an embodiment overcomes all or part of the disadvantages of known devices delivering a voltage to a variable capacitor of a voltage-controlled oscillator, for example a voltage-controlled oscillator controlled by a phase-locked loop.

An embodiment provides a device comprising: a first bandgap circuit configured to apply a temperature-stable voltage across a first resistive element so that a first current flows therethrough, and to deliver a second current proportional to absolute temperature;
a second resistive element comprising one or a plurality of MOS transistors in series and each connected as a diode, the second resistive element having a first terminal connected to a node of application of a reference potential and a second terminal coupled to a node of application of a power supply potential;
a second circuit connected to the first circuit and configured to deliver a first copy of the first current and so that the first copy flows through the second resistive element; and
a third circuit connected to the first circuit and configured to:
   deliver a copy of the second current, deliver a first control voltage from the copy of the second current, and apply the first control voltage to a back gate of the transistors of the resistive element, or
   deliver a second copy of the first current and a copy of the second current, deliver a first control voltage from a difference between the second copy of the second current and the copy of the first current, and apply the first control voltage to a back gate of the transistors of the second resistive element.

According to an embodiment, the second terminal of the second resistive element is configured to deliver a bias voltage to a variable capacitor.

According to an embodiment, the device comprises the variable capacitor, the variable capacitor is configured to receive a tuning voltage and the bias voltage, and a difference between the tuning voltage and the bias voltage determines a value of the capacitance.

According to an embodiment, the second resistive element is in series with a resistor, the second terminal of the second resistive element is configured to deliver a first bias voltage to a variable capacitor and is connected to a first terminal of the resistor, and a second terminal of the resistor is configured to deliver a second bias voltage to the variable capacitor.

According to an embodiment, the device comprises the variable capacitor, the variable capacitor is configured to receive a tuning voltage and the first and second bias voltages, and a difference between the tuning voltage and the first bias voltage and a difference between the tuning voltage and the second bias voltage determine a value of the capacitance.

According to an embodiment, the device comprises a voltage-controlled oscillator comprising variable the capacitor.

According to an embodiment, the device comprises a circuit for delivering the tuning voltage, the circuit comprising, for example, a phase-locked loop.

According to an embodiment, the third circuit comprises a resistor having a first terminal connected to the node of application of the reference potential or to the node of application of the power supply potential, a second terminal of the resistor being configured to deliver the first control voltage and being connected to the back gate of the transistors of the second resistive element.

According to an embodiment, the third circuit comprises a smoothing capacitor connected between the back gate of the transistors of the second resistive element and the node of application of the reference potential.

According to an embodiment, the transistors of the second resistive element all are N-channel transistors or all are P-channel MOS transistors.

According to an embodiment, the transistors of the second resistive element are all implemented on silicon on insulator.

According to an embodiment, the third circuit comprises a circuit for adjusting a slope of the first control voltage with temperature.

According to an embodiment, the adjustment circuit comprises one or a plurality of assemblies, each comprising:
a first resistor and a first switch in series between the node of application of the power supply potential and the second terminal of the resistor delivering the first control voltage, and
a second resistor and a second switch in series between the second terminal of the resistor delivering the first control voltage and the node of application of the reference potential, a value of the second resistor of the assembly being identical to a value of the first resistor of the assembly.

According to an embodiment, the adjustment circuit comprises a plurality of the assemblies, and a value of the first resistance is different in each of the assemblies.

According to an embodiment, the first control voltage is determined by the difference between the second copy of the first current and the copy of the second current, and the slope adjustment circuit comprises a fourth circuit configured to deliver the second copy of the first current, and a fifth circuit configured to deliver the second copy of the second current, a gain of the fourth circuit and a gain of the fifth circuit being adjustable in such a way as to allow the adjustment of the slope of the first control voltage with temperature.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, schematically and in the form of blocks, an example of a circuit comprising a variable capacitor;

FIG. 2 schematically shows an example of a variable capacitor;

FIG. 3 schematically shows another example of a variable capacitor;

FIG. 4 shows with curves an example of operation of a circuit comprising a variable capacitor;

FIG. 5 shows, schematically and partly in the form of blocks, an embodiment of a device;

FIG. 6 shows an example of another embodiment of a circuit of the device of FIG. 5;

FIG. 7 shows an example of still another embodiment of the circuit of FIG. 6;

FIG. 8 shows another embodiment of a resistive component of the device of FIG. 5;

FIG. 9 shows alternative embodiment of the circuit of FIG. 5; and

FIG. 10 shows an example of embodiment of another circuit of the device of FIG. 5.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, etc., “right”, or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

FIG. 1 shows, schematically and in the form of blocks, an example of a circuit VCO comprising a variable capacitor Cvar.

Circuit VCO is a voltage-controlled oscillator. Circuit VCO is configured to deliver a signal OUT at a frequency Fvco having a value determined by the value of a tuning voltage Vtune. More particularly, tuning voltage Vtune is a voltage for adjusting the capacitance value of variable capacitor Cvar, and the value of the frequency Fvco of signal OUT is at least partly determined by the capacitance value of component Cvar. Voltage Vtune is, for example, received by a terminal 104 of capacitor Cvar.

In this example, capacitor Cvar also receives a bias voltage Vbias1. Voltage Vbias1 is, for example, received by a terminal 106 of capacitor Cvar. The capacitance value of capacitor Cvar, for example between two terminals 100 and 102 of component Cvar, is then determined by the difference between voltages Vtune and Vbias1.

Although this is not illustrated in FIG. 1, in other examples, capacitor Cvar is configured to receive, in addition to voltages Vtune and Vbias1, another bias voltage Vbias2. In these other examples, the capacitance value of component Cvar is then determined by the difference between voltages Vtune and Vbias1 and by the difference between voltages Vtune and Vbias2, the difference between voltages Vbias1 and Vbias2 being kept constant.

As an example, the frequency Fvco of signal OUT is controlled by a phase-locked loop (not shown in FIG. 1). The phase-locked loop is, for example, configured to deliver, or control, voltage Vtune so that frequency Fvco is equal to a set point frequency Flock.

As an example, the VCO circuit and the phase-locked loop controlling the frequency Fvco of signal OUT form part of a radio frequency circuit and are configured so that the frequency Fvco of signal OUT is greater than 1 GHZ, preferably greater than 10 GHZ, for example approximately equal to 20 GHZ. As an example, the radio frequency circuit is a clock signal generation circuit. As an alternative or complementary example, the radio frequency circuit forms part of a circuit for transmitting and/or receiving a wireless radio frequency signal.

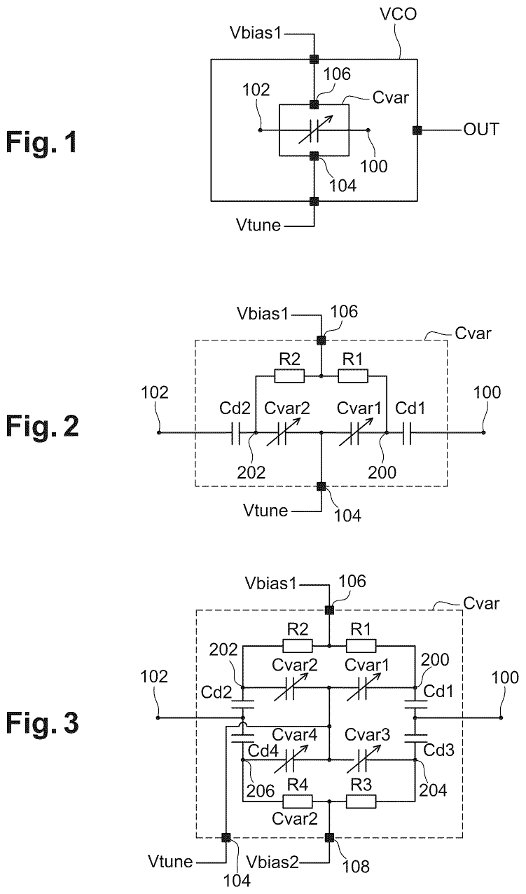

FIG. 2 schematically shows an example of a variable capacitor Cvar.

In this example, capacitor Cvar comprises two variable-capacitance components Cvar1 and Cvar2, for example two varactors (or variable-capacitance diodes). The capacitance value of each of components Cvar1 and Cvar2 is determined by the voltage across this component. Each of components Cvar1 and Cvar2 has one electrode coupled, preferably connected, to the terminal 104 receiving voltage Vtune, and another terminal coupled to the terminal 106 receiving voltage Vbias1. For example, dipole Cvar1 is connected between terminal 104 and a node 200 coupled to terminals 106 and 100, dipole Cvar2 being connected between terminal 104 and a node 202 coupled to terminals 106 and 102. For example, node 200, respectively 202, is coupled to terminal 106 by a resistor R1, respectively R2, resistor R1, respectively R2, being for example connected between nodes 200 and 106, respectively between nodes 202 and 106. For example, node 200, respectively 202, is coupled to terminal 100, respectively 102, by a decoupling capacitor Cd1, respectively Cd2, capacitor Cd1, respectively Cd2, being for example connected between nodes 200 and 100, respectively between nodes 202 and 102.

Voltage Vbias1 is a voltage for biasing component Cvar, and generally has a constant value. By varying the value of voltage Vtune, the voltage across each of components Cvar1 and Cvar2 is modified, which results in a change in the capacitance value of each of components Cvar1 and Cvar2, and thus in the capacitance value of component Cvar.

FIG. 3 schematically shows another example of a variable capacitor Cvar.

The capacitor Cvar of FIG. 3 comprises all the elements of the capacitor Cvar of FIG. 2. Thus, unless otherwise indicated, all that has been described for the capacitor Cvar of FIG. 2 applies to the capacitor Cvar of FIG. 3.

Further, the capacitor Cvar of FIG. 3 comprises two variable-capacitance components Cvar3 and Cvar4, for example two varactors. The capacitance value of each of components Cvar3 and Cvar4 is determined by the voltage across this component. Each of components Cvar3 and Cvar4 has one electrode coupled, preferably connected, to the terminal 104 receiving voltage Vtune, and another terminal coupled to a terminal 108 of component Cvar, terminal 108 receiving voltage Vbias2. For example, dipole Cvar3 is connected between terminal 104 and a node 204 coupled to terminals 108 and 100, dipole Cvar4 being connected between terminal 104 and a node 206 coupled to terminals 108 and 102. For example, node 204, respectively 206, is coupled to terminal 108 by a resistor R3, respectively R4, resistor R3, respectively R4, being for example connected between nodes 204 and 108, respectively between nodes 206 and 108. For example, node 204, respectively 206, is coupled to terminal 100, respectively 102, by a decoupling capacitor Cd3, respectively Cd4, capacitor Cd3, respectively Cd4, being for example connected between nodes 204 and 100, respectively between nodes 206 and 102.

Voltage Vbias2 is a voltage for biasing component Cvar, and generally has a constant value. Further, the difference between voltages Vbias1 and Vbias2 is preferably constant. By varying the value of the voltage Vtune, the voltage across each of the components Cvar1, Cvar2, Cvar3, and Cvar4 is then modified, which results in a change in the capacitance value of each of components Cvar1, Cvar2, Cvar3, and Cvar4, and thus in the capacitance value of component Cvar.

The capacitor Cvar of FIG. 3, due to the presence of two bias voltages Vbias1 and Vbias2 rather than of bias voltage Vbias1 only as in FIG. 2, exhibits a variation in its capacitance value with voltage Vtune, which is more linear than that of the capacitor Cvar of FIG. 2. Thus, when capacitor Cvar is used to adjust the frequency of a voltage-controlled oscillator, the variation of the oscillator frequency with voltage Vtune is more linear when the capacitor Cvar of FIG. 3 is used than when the capacitor Cvar of FIG. 2 is used.

As mentioned hereabove, circuits comprising a variable capacitor have an operation which may depend on temperature in addition to the value of their variable capacitance, which poses a problem. This is for example the case in voltage-controlled oscillators, such as the VCO oscillator of FIG. 1, which have their frequency controlled by a phase-locked loop.

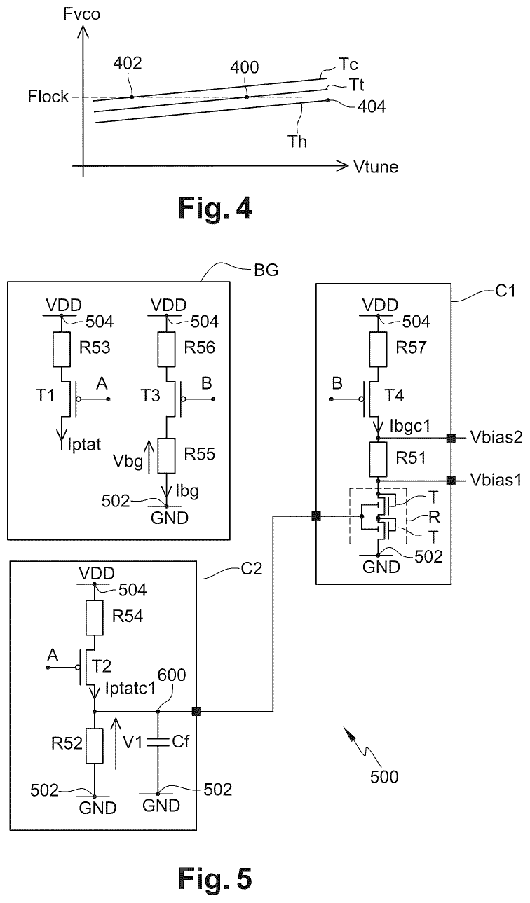

FIG. 4 illustrates with curves an example of operation of the VCO oscillator of FIG. 1 when the oscillator has its frequency Fvco controlled by a phase-locked loop to set point value Flock.

A curve Tt illustrates the variation, at a nominal operating temperature, for example room temperature, of the frequency Fvco of the signal OUT of the VCO oscillator as a function of voltage Vtune.

In this example, frequency Fvco increases, for example substantially linearly, with the value of voltage Vtune.

The phase-locked loop controls voltage Vtune to a value such that frequency Fvco is equal to frequency Flock (point 400 in FIG. 4). The phase-locked loop is then the to be locked.

A curve Tc illustrates the variation of the frequency Fvco of the signal OUT of the VCO oscillator as a function of voltage Vtune, at a low temperature lower than the nominal temperature. A curve Th illustrates the variation of the frequency Fvco of the signal OUT of the VCO oscillator as a function of voltage Vtune, at a high temperature, higher than the ambient temperature.

In this example, for a given voltage value Vtune, frequency Fvco decreases when the temperature rises. Curve Tc then corresponds to a translation of curve Tt towards higher frequencies Fvco, and curve Th then corresponds to a translation of curve Tt towards lower frequencies Fvco.

Since the frequency Fvco of the VCO oscillator is controlled by the value Flock by the phase-locked loop, in this example where frequency Fvco increases with the increase of voltage Vtune and decreases with the temperature rise, the loop decreases the value of voltage Vtune when the temperature decreases to maintain frequency Fvco equal to frequency Flock. In particular, at the low temperature corresponding to curve Tc, voltage Vtune is decreased to a value corresponding to a point 402 in FIG. 4, for which curve Tc takes value Flock. Symmetrically, the loop increases the value of voltage Vtune when the temperature rises to maintain frequency Fvco equal to frequency Flock. In particular, at the high temperature corresponding to curve Tc, voltage Vtune is increased to a value corresponding to a point 404 of curve Th. However, as shown in FIG. 4, at the point 404 corresponding to the maximum value that voltage Vtune can take, frequency Fvco is lower than frequency Flock, and the phase-locked loop is no longer locked.

The fact that the phase-locked loop can no longer be locked when the temperature varies with respect to the nominal operating temperature may arise when the temperature rises or decreases with respect to the nominal temperature, in circuits where frequency Fvco increases when voltage Vtune increases as illustrated in FIG. 4, but also in circuits where frequency Fvco decreases when voltage Vtune increases, and/or in circuits where frequency Fvco increases when the temperature decreases as shown in FIG. 4, but also in circuits where frequency Fvco decreases when the temperature decreases.

For example, the variation of frequency Fvco with temperature is at least partly linked to the variation of the capacitance value of component Cvar with temperature, and, more generally, to the variation with temperature of the values of the components of the oscillator tank.

To decrease the temperature dependency of frequency Fvco, that is, to bring curves Tc and Th closer to curve Tt, it could be envisaged to replace the component Cvar of the VCO circuit with two components Cvar in parallel, one being controlled by voltage Vtune as previously described, and the other being controlled by a voltage determined by temperature to compensate for the variation of frequency Fvco with temperature.

However, in addition to increasing the surface area of capacitor Cvar, and thus of the VCO circuit, this also increases the number of parasitic capacitors, which poses a problem, particularly in the radio frequency field.

While usually the bias voltage(s) Vbias1 and Vbias2 of a variable capacitor are constant and do not depend on temperature, it is here provided to make them temperature-dependent.

For example, it is here provided to make the bias voltage Vbias1 of a variable capacitor receiving only one bias voltage, or the two bias voltages Vbias1 and Vbias2 of a variable capacitor receiving two bias voltages, temperature-dependent. The way in which this or these bias voltages are temperature-dependent (increasing with temperature) is determined in such a way as to compensate for the effect of temperature variation on the operation of an electronic circuit comprising a variable capacitor having its capacitance value determined by the difference between a control voltage Vtune and each bias voltage that it receives. According to an embodiment where the variable capacitor receives two bias voltages, it is provided for the difference between the two bias voltages to remain constant when the temperature varies.

Thus, there is here provided a device configured to deliver one or a plurality of voltages for biasing a variable capacitor, each of which is temperature-dependent, for example in such a way as to compensate for the effect of the temperature variation on the operation of a circuit comprising such a variable capacitor. The choice of the way in which each of the variable capacitor bias voltages varies with temperature, for example increases as the temperature rises or decreases as the temperature rises, depends on the application. For example, the choice of the way in which each of the bias voltages varies according to temperature is made so as to compensate for temperature variations of a parameter having a value at least partly determined by that of the capacitor.

As an example, the circuit is an oscillator, for example configured to deliver a radio frequency signal, and the variable capacitor forms part of the oscillator “tank”. The variation of the bias voltages of the variable capacitor with temperature is then configured to compensate for a variation of the oscillator frequency Fvco with temperature. Indeed, frequency Fvco depends on the value of the capacitance of the oscillator tank and, more generally, on the value of each of the components of this tank, and the values of these components vary with temperature.

FIG. 5 shows, schematically and partly in the form of blocks, an embodiment of such a device 500.

Device 500 comprises a bandgap circuit designated with reference BG in FIG. 5.

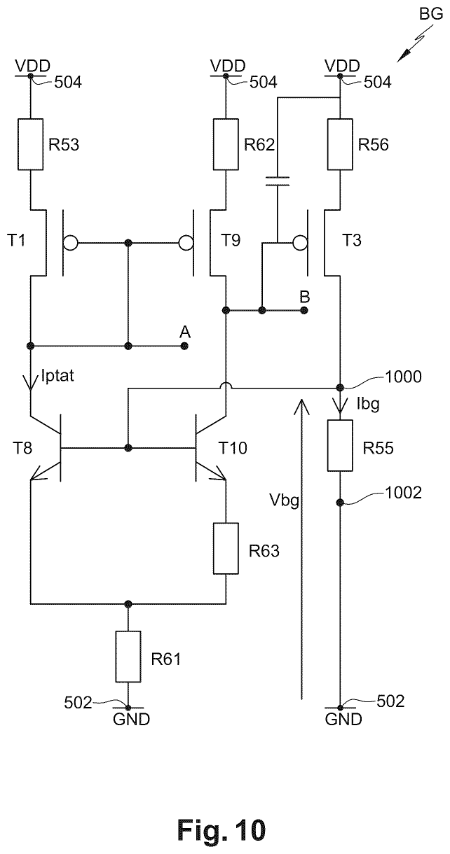

Circuit BG comprises a resistive element R55 and is configured to apply a temperature-stable voltage across resistive element R55, so that a current Ibg flows therethrough. In other words, circuit BG is configured to generate the temperature-stable voltage Vbg, and to impose this voltage across resistive element R55. A detailed example of circuit BG will be described hereafter in relation with FIG. 10. In addition to current Ibg, circuit BG is further configured to deliver a current Iptat depending on temperature, preferably linearly with temperature. Current Iptat is a current proportional to absolute temperature (PTAT) which increases when the temperature rises.

Device 500 also comprises a circuit C1. Circuit C1 comprises a resistive element R. Resistive element R has a terminal connected to a node 502 configured to receive a reference potential GND, for example the ground. Element R is configured to deliver voltage Vbias1, this voltage Vbias1 then being available across element R. Voltage Vbias1 is a bias voltage of a variable capacitor, for example of a variable capacitor Cvar.

Element R comprises, preferably is formed of, one or a plurality of MOS (Metal Oxide Semiconductor) transistors in series between the conduction terminals of resistive element R. Each of these transistors T is diode-assembled, that is, has its drain connected to its gate. When component R comprises a plurality of transistors T, the latter are all of the same type, for example, they are all NMOS transistors, as is the case in the example of FIG. 5, where component R comprises exactly two N-channel (or NMOS) transistors T. Preferably, transistors T are all identical. As an example, an advantage of implementing resistive element R with Q transistors T in series, each diode-assembled, is that the small-signal resistance is in Q/gm and is thus low, Q being an integer greater than or equal to 1, and gm being the transconductance of a transistor T. This result in low noise on the voltages available across the terminals of resistive element R.

Circuit C1 is connected to circuit BG and is configured to deliver a copy Ibgc1 of current Ibg to resistive element R. In other words, circuit C1 is configured to deliver a current Ibgc1 which is a copy of current Ibg, and so that this current Ibgc1 flows between the conduction terminals of component R.

In the remainder of the present disclosure, unless otherwise specified, when it is indicated that a first current is a copy of a second current, this means that the first current is equal to the second current to within a multiplication factor.

Device 500 further comprises a circuit C2. Circuit C2 is connected to circuit BG. Circuit C2 is configured to deliver a temperature-dependent bias voltage V1 to the back gates of the transistors T of element R. Thus, when the temperature varies, voltage V1 varies, which modifies the resistance value of each of transistors T, and thus the value of the voltage Vbias1 available across element R, that is, the voltage Vbias1 available across the terminal of element R which is not connected to node 502.

Since transistors T have back gates, they are thus implemented on SOI (Semiconductor On Insulator), for example on FDSOI (Fully Depleted Silicon On Insulator).

In the embodiment of FIG. 5, circuit C2 is more particularly configured to deliver a copy Iptatc1 of current Iptat and so that voltage V1 is determined by current Iptatc1, for example, varies linearly with this current Iptatc1. Thus, when the temperature varies, current Iptat varies, whereby current Iptatc1 varies, resulting in a corresponding variation of voltage V1. The variation of voltage V1 results in a variation of the resistance value of component R, and thus in a corresponding variation of voltage Vbias1. Accordingly, by not changing the value of voltage Vtune, the capacitance value of a variable capacitor such as that of FIG. 2 is modified when the temperature varies.

In the embodiment shown in FIG. 5, device 500 is configured to also deliver bias voltage Vbias2 in addition to voltage Vbias1. Voltages Vbias1 and Vbias2 are bias voltages of a variable capacitor, for example of the variable capacitor Cvar of FIG. 3. For this purpose, in circuit C1, resistive element R is connected in series with a resistor R51. Thus, a terminal of element R is connected to node 502, another terminal of element R is connected to a terminal of resistor R51 and delivers voltage Vbias1, and the other terminal of resistor R51 delivers voltage Vbias2. Preferably, resistor R51 is matched to resistor R55, whereby the difference between voltages Vbias1 and Vbias2 is constant and, in particular, does not depend on temperature, since current Ibgc1 is a copy of current Ibg equal to Vbg/R55.

According to an embodiment, when device 500 is configured to deliver both voltages Vbias1 and Vbias2, device 500 comprises a variable capacitor (not shown in FIG. 5) configured to receive bias voltages Vbias1 and Vbias2 and tuning voltage Vtune and having its capacitance value determined by the difference between voltages Vbias1 and Vtune and by the difference between voltages Vbias2 and Vtune. As an example, this variable capacitor is the capacitor Cvar described in relation with FIG. 3. According to an embodiment, the device further comprises a voltage-controlled oscillator, for example the VCO oscillator of FIG. 1, comprising this variable capacitor. According to an embodiment, the device comprises a circuit for delivering voltage Vtune, for example a phase-locked loop.

In another embodiment, non-illustrated, device 500 is configured to only deliver bias voltage Vbias1. In this other embodiment, resistor R51 may be omitted.

According to an embodiment, when device 500 is configured to only deliver bias voltage Vbias1, device 500 comprises a variable capacitor configured to receive voltage Vbias1 and a control voltage Vtune, and having its capacitance value determined by the difference between voltages Vbias1 and Vtune. As an example, this variable capacitor is the capacitor Cvar described in relation with FIG. 2. According to an embodiment, the device further comprises a voltage-controlled oscillator, for example the VCO oscillator of FIG. 1, comprising this variable capacitor. According to an embodiment, the device comprises a circuit for delivering voltage Vtune, for example a phase-locked loop.

According to an embodiment, as illustrated in FIG. 5, circuit C2 comprises a resistor R52 configured to deliver voltage V1. Resistor R52 has a terminal connected to node 502 and another terminal connected to the back gate of transistors T (or node 600), voltage V1 being available on this other terminal. In the example of embodiment of FIG. 5, circuit C2 is configured to deliver current Iptatc1 to node 600. Current Iptatc1 then flows between the terminals of resistor R52, which converts current Iptatc1 into voltage V1.

As an example, resistor R52 has a value such that, at the nominal operating temperature, voltage V1 is equal to half a power supply potential VDD of device 500, potential VDD being preferably positive and referenced to potential GND.

Preferably, circuit C2 comprises a smoothing capacitor Cf connected between node 600 and node 502.

As an example, circuit BG comprises a P-channel MOS transistor T1 configured so that current Iptat flows therethrough, and circuit C2 comprises s a P-channel MOS transistor T2 mirror-assembled with transistor T1 so that transistor T2 delivers current Iptatc1 to node 600. Transistor T2 is, in the example shown in FIG. 5, connected to node 600 and in series with resistor R52 configured to deliver voltage V1.

As a more detailed example, transistor T1 has its source coupled to a node 504 configured to receive power supply potential VDD, for example via a resistor R53, resistor R53 preferably having one terminal connected to transistor T1 and one terminal connected to node 504. The gate of transistor T1 is connected to node A. Transistor T2 then has its gate connected to node A and its source coupled to node 504, for example by a resistor R54, resistor R54 preferably having one terminal connected to transistor T2 and one terminal connected to node 504.

As an example, circuit BG further comprises a P-channel MOS transistor T3 configured so that current Ibg flows therethrough, and circuit C1 comprises a P-channel MOS transistor T4 mirror-assembled with transistor T3 so that transistor T4 delivers current Ibgc1. Transistor T4 is series-connected with resistive element R. Transistor T3 is, for example, series-connected with resistive element R55, across which circuit BG applies temperature-stable voltage Vbg. Resistive element R55, for example a resistor, has a terminal connected to node 502. As a result, current Ibg flows between the terminals of element R55, that is, through element R55, and through transistor T3 series-connected with element R55 between nodes 504 and 502. Transistor T3 has its source coupled to node 504, for example via a resistor R56, resistor R56 having one terminal connected to transistor T3 and one terminal connected to node 504. The gate of transistor T3 is connected to node B. Transistor T4 then has its gate connected to node B and its source coupled to node 504, for example by a resistor R57, resistor R57 preferably having one terminal connected to transistor T4 and one terminal connected to node 504. Transistor T4 is in series with resistor R57 between nodes 504 and 502.

In the example of embodiment described in relation with FIG. 5, circuit C2 is configured to deliver current Iptatc1, which is a copy of current Iptat, to deliver the voltage V1 determined by current Iptatc1, and to apply voltage V1 to the back gate of the transistors T of resistive element R.

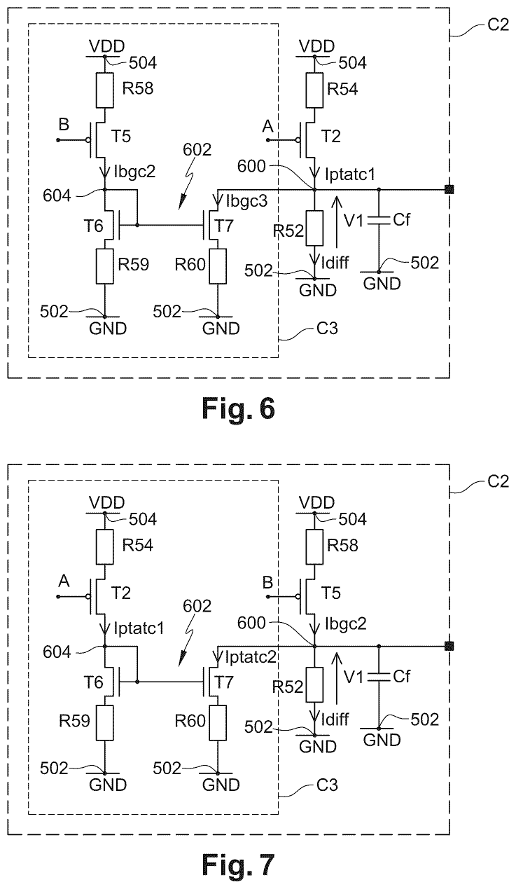

In other examples of embodiments, as will be described in relation with FIGS. 6 and 7, circuit C2 is configured to deliver a copy of current Ibg to node 600 and a copy of current Iptat to node 600, to deliver voltage V1 which is then determined by a difference between these two current copies, and to apply voltage V1 to the back gate of the transistors T of resistive element R.

FIG. 6 shows an example of such an embodiment of circuit C2.

The circuit C2 of FIG. 6 comprises, like the example of circuit C2 described in relation with FIG. 5, transistor T2 configured to deliver current Iptatc1. Transistor T2 has its source coupled to node 504, for example by resistor R54, and its drain coupled, for example connected, to node 600, corresponding to the node of connection of transistor T2 to resistor R52.

Circuit C2 further comprises a circuit C3 configured to deliver a copy Ibgc3 of current Ibg.

Current Ibgc3 is delivered to node 600 so that a current Idiff flowing through resistor R52 is equal to the difference between currents Iptatc1 and Ibgc3. More precisely, in the example of FIG. 6, circuit C3 is configured so that current Idiff is equal to current Iptatc1 minus current Ibgc3. Thus, when the temperature rises, current Idiff increases, whereby voltage V1 increases.

As an example, circuit C3 comprises a P-channel MOS transistor T5 configured to deliver a copy Ibgc2 of current Ibg, transistor T5 being mirror-assembled with transistor T3. For example, transistor T5 has its source coupled to node 504, for example via a resistor R58, resistor R58 preferably having one terminal connected to transistor T5 and one terminal connected to node 504. The gate of transistor T5 is connected to node B. The drain of transistor T5 is coupled to node 600.

In the example of FIG. 6, transistor T5 is coupled to node 600 by a current mirror 602 comprising an N-channel MOS transistor, current mirror 602 here being configured to deliver current Ibgc3 based on current Ibgc2. For example, current mirror 602 comprises an N-channel MOS transistor T6 having its drain connected to a node 604 and its source coupled to node 502, for example by a resistor R59, resistor R59 for example having one terminal connected to node 502 and one terminal connected to the source of transistor T6. The gate of transistor T6 is connected to the drain of transistor T6. Current mirror 602 further comprises an N-channel MOS transistor T7 having its drain connected to node 600 and its source coupled to node 502, for example by a resistor R60, resistor R60 having for example one terminal connected to node 502 and one terminal connected to the source of transistor T7. The gate of transistor T7 is connected to the gate of transistor T6. In the example of FIG. 6, transistor T5 is connected to node 604 by its drain.

FIG. 7 shows an example of another embodiment of circuit C2.

As compared with FIG. 6, in the example of FIG. 7, circuit C2 is configured so that the current Idiff through resistor R52 is equal to the difference between the copy Ibgc2 of current Ibg and a copy Iptatc2 of current Iptat, and, more precisely, so that current Idiff is equal to current Ibgc2 minus current Iptatc2. Thus, when the temperature rises, current Idiff decreases, whereby voltage V1 decreases.

The circuit C2 of FIG. 7 thus differs from the circuit C2 of FIG. 6 in that:
the transistor T2 configured to deliver current Iptatc1 to node 600 in the circuit C2 of FIG. 6 has been replaced with the transistor T5 configured to deliver current Ibgc2 in the circuit C2 of FIG. 7, so that current Ibgc2 is delivered to node 600; and
the circuit C3 of the circuit C2 of FIG. 7 is not configured to deliver current Ibgc3 to node 600, as was the case in FIG. 6, but to deliver current Iptatc2 to node 600.

For example, transistor T5 remains mirror-assembled with transistor T3, with its gate connected to node B, its source coupled to node 504, for example via resistor R58, but its drain is connected to node 600 rather than to node 604 as was the case in FIG. 6. Symmetrically, transistor T2 remains mirror-assembled with transistor T1, with its gate connected to node A, its source coupled to node 504, for example via resistor R54, but its drain is connected to node 604 coupled to node 600 by current mirror 602. Current mirror 602 then delivers current Iptatc2 from current Iptatc1.

In the device 500 described hereabove in relation with FIGS. 5 to 7, the resistive element is formed of MOS transistors in series, each diode-assembled. This enables to decrease the noise on voltage Vbias1 as compared with a device in which a temperature-dependent current would have been directly supplied to a resistor to obtain voltage Vbias across this resistor.

Further, the provision of the component R such as described enables to adapt the gain between a temperature variation and a corresponding variation of voltage Vbias1 by modifying the number of transistors T in component R.

In the examples and variants described hereabove, component R comprises, preferably is formed of, one or a plurality of N-channel MOS transistors T.

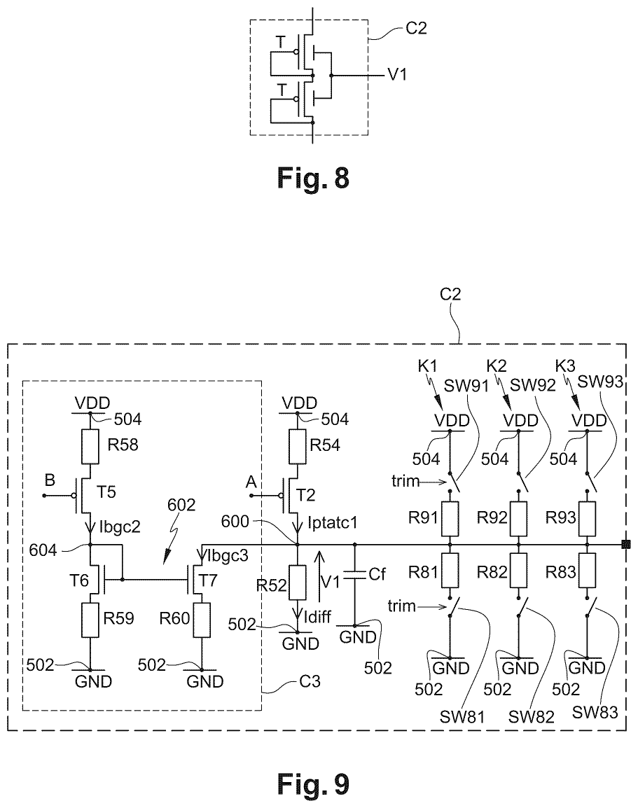

FIG. 8 shows another example of the resistive component R of the device of FIG. 5.

In the component R of the embodiment of FIG. 8, each transistor T of component R has a P channel rather than an N channel as previously described.

Although this is not illustrated in FIG. 8, the drain of transistors T is then on the side of node 502. For example, the transistor T of the resistive element R which has a terminal connected to node 502 has its drain connected to node 502.

As compared with the case where transistors T have an N channel, the variation direction of voltage V1 with temperature is reversed for a corresponding case where transistors T have a P channel, so that the variation direction of voltage Vbias1 with temperature remains the same.

FIG. 9 shows an alternative embodiment of circuit C2. In FIG. 9, the alternative embodiment is applied to the circuit C2 of FIG. 6, although this variant may also be applied to the circuit C2 of FIG. 7, this last implementation being within the abilities of those skilled in the art based on the description made hereafter in relation with FIG. 9.

In this variant, circuit C2 comprises a circuit for adjusting the slope of voltage V1 with temperature, and thus the slope of voltage Vbias1 with temperature. This enables to adjust the way in which the variation of frequency Fvco with temperature is compensated for by the variation of voltage Vbias1 with temperature, for example so that, for a given voltage Vtune, the variation of frequency Fvco with temperature is as small as possible.

More specifically, in the example of FIG. 9, this adjustment circuit comprises a plurality of assemblies Ki, where i is a positive integer. In the example of FIG. 9, i is equal to 3.

Each assembly Ki (K1, K2, K3 in FIG. 9) comprises:
a resistor R81 (R81, R82, R83 in FIG. 9) and a switch SW8i (SW81, SW82, SW83 in FIG. 9) series-connected between node 600 and node 502; and
a resistor R9i (R91, R92, R93 in FIG. 9) and a switch SW9i (SW91, SW92, SW93 in FIG. 9) series-connected between node 600 and node 504.

For example, in each assembly Ki, switch SW8i is connected to node 502 and switch sw9i is connected to node 504.

In each assembly Ki, the resistor R8i of the assembly is identical to the resistor R9i of this assembly Ki. For example, each resistor R8i is matched to the corresponding resistor R9i. Further, for each assembly Ki, the value of the resistors R8i and R9i of assembly Ki is preferably different from that of the resistors R8i and R9i of the other assemblies Ki.

For example, in a configuration the to be “binary”, for i greater than or equal to 2, the value of the resistor R9i, respectively R8i, of index i is equal to twice the value of the resistor R9i-1, respectively R8i-1, of index i-1. For example, in each assembly Ki, the value of the resistors R8i and R9i in the assembly is a multiple of the value of resistor R52. For example, in each assembly Ki, the value of resistors R8i and R9i is equal to 2 (i-1) times the value of resistor R52.

As another example, in a configuration the to be “thermometric”, the value of each resistor R8i, respectively R9i, is determined, for example during an adjustment or calibration phase, independently from the value of the other resistors R8i, respectively R9i.

The switches SW8i and SW9i of assemblies Ki are controlled by a digital signal trim delivered by a circuit, not shown. For example, signal trim comprises i bits, each bit of signal trim controlling a corresponding assembly Ki. Signal trim is configured so that the switches SW9i and SW8i of the same assembly Ki are in the same on or off state.

In another non-illustrated example of implementation of the circuit for adjusting the slope of voltage Vbias1 with temperature, the adjustment circuit comprises:
a circuit configured to deliver the copy of current Iptat to node 600, that is, the transistor T2 delivering copy Iptatc1 in the embodiment of FIG. 6 and the circuit C3 delivering the copy Iptatc2 in the embodiment of FIG. 7; and
a circuit configured to deliver the copy of current Ibg to the node 600, that is, the circuit C3 delivering copy Ibgc3 in the embodiment of FIG. 6, and the transistor T5 delivering copy Ibgc2 in the embodiment of FIG. 7, and, further, the gain of the circuit delivering the copy of current Ibg to node 600 is adjustable, just as the gain of the circuit delivering the copy of current Iptat to node 600.

Thereby, the adjustment of the gains of these two circuits enables to adjust or set the slope of voltage V1, and thus of voltage Vbias1, with temperature.

In the described embodiments, when the copy Iptatc1 of current Iptat which is delivered to node 600 corresponds to a positive current (as in FIG. 6), voltage V1 increases with temperature. Conversely, when the copy Iptatc2 of the current Iptat supplied to node 600 corresponds to a negative current, that is, a positive current Iptatc2 drawn from node 600 (case of FIG. 7), voltage V1 decreases with temperature.

There is considered as an example the case where the circuit configured to deliver the copy of current Iptat to node 600 comprises transistor T2 in series with resistor R52 (FIG. 6), and where the circuit configured to deliver the copy of current Ibg to node 600 corresponds to the circuit C3 of FIG. 6. In this example, transistor T2 is implemented by a plurality of P-channel MOS transistors selectively connected in parallel with one another by switches controlled by a first control signal, so that the current Iptatc1 delivered by transistor T2 to node 600 is equal to α*Iptatunit, with α a factor, preferably integer, having its value depending on the state of the first control signal, and Iptatunit a current determined by current Iptat, for example proportional or equal to current Iptat. Still in this example, transistor T7 (or alternatively transistor T5, although this may result in the source drain saturation voltage of transistor T7 not being constant, which causes saturation problems for transistor T7 at high currents) is implemented by a plurality of N-channel MOS transistors (P-channel when this concerns transistor T5) selectively connected in parallel with one another by switches controlled by a second control signal, so that the current Ibgc3 delivered by transistor T7 to node 600 is equal to β*Ibgunit, with β a factor, preferably integer, having its value depending on the state of the second control signal, and Ibgunit a current determined by current Ibg, for example proportional or equal to current Ibg. The modification of the values of gains α and β then enables to adjust the slope of voltage V1, and thus of voltage Vbias1, with temperature.

Preferably, in the above example, the values of gains α and β and of currents Ibgunit and Iptatunit are configured so that, at the nominal operating temperature, voltage V1 is equal to VDD/2. In other words, gains α and β are selected so that, at the nominal operating temperature, α*Iptatunit−β*Ibgunit=VDD/(2*R52), which sets the relationship between α and β, for example because the currents Iptatunit and Ibgunit at the nominal temperature are known. For example, when, at the nominal operating temperature Iptatunit, is equal to Ibgunit and to current Idiff with V1 equal to VDD/2, gains α and β verify α-β=1.

The case where the circuit configured to deliver the copy of current Iptat to node 600 corresponds to circuit C3 (FIG. 7) and where the circuit configured to deliver the copy of current Ibg to node 600 comprises transistor T5 in series with resistor R52 (FIG. 7) is considered as another example. In this example, transistor T5 is implemented by a plurality of P-channel MOS transistors selectively connected in parallel with one another by switches controlled by a first control signal, so that the current Ibgc2 delivered by transistor T5 to node 600 is equal to β*Ibgunit, with β a factor, preferably integer, having its value depending on the state of the first control signal, and Ibgunit a current determined by current Ibg, for example proportional or equal to current Ibg. Still in this example, transistor T7 (or alternatively transistor T2, although this may result in the source drain saturation voltage of transistor T7 not being constant, which results in saturation problems for transistor T7 at high currents) is implemented by a number of N-channel MOS transistors (P-channel when this concerns transistor T2) selectively connected in parallel with one another by switches controlled by a second control signal, so that the current Ipatc2 supplied by transistor T7 to node 600 is equal to α*Iptatunit, with α a factor, preferably integer, having its value depending on the state of the second control signal, and Iptatunit a current determined by current Iptat, for example proportional or equal to current Iptat. The modification of the values of gains α and β then enables to adjust the slope of voltage V1, and thus of voltage Vbias1, with temperature.

Preferably, in the above example, the values of gains α and β and of currents Ibgunit and Iptatunit are configured so that, at the nominal operating temperature, voltage V1 is equal to VDD/2. In other words, gains α and β are selected so that, at the nominal operating temperature, β*Ibgunit−α*Iptatunit=VDD/(2*R52), which sets the relationship between α and β, for example because the currents Iptatunit and Ibgunit at the nominal temperature are known. For example, when, at the nominal operating temperature, Iptatunit is equal to Ibgunit and to current Idiff with V1 equal to VDD/2, the gains α and β verify β−α=1.

In the above-described embodiments and variants, resistor R52 is connected between node 600 and node 502. In other embodiments and variants, as compared with what has been previously described, resistor R52 is connected between node 600 and node 504. The implementation of these other embodiments and variants is within the abilities of those skilled in the art based the functional indications given hereabove.

FIG. 10 illustrates an example of a circuit BG that can be used to implement device 500, it being understood that those skilled in the art may provide using other circuits BG.

In this example, circuit BG comprises transistor T1 having its source coupled to node 504, for example by resistor R53, its gate connected to node A, and its drain connected to its gate, and transistor T3 having its source coupled to node 504, for example by resistor R56, its gate connected to node B, and its drain connected to a terminal 1000 of resistor R55, the other terminal 1002 of resistor R55 being connected to node 502. As an example, a compensation capacitor is connected between the gate B of transistor T3 and node 504, to improve the stability.

Circuit BG further comprises an NPN bipolar transistor T8 coupling the drain A of transistor T1 to node 502. Transistor T8 has, for example, its collector connected to node A, and its emitter coupled to node 502 by a resistor R61. The base of transistor T8 is connected to terminal 1000 of resistor R55.

Circuit BG also comprises a P-channel MOS transistor T9 mirror-assembled with transistor T1. Transistor T9 has, for example, its gate connected to node A, its source coupled to node 502, for example via a resistor R62 preferably connected between node 504 and transistor T9. An NPN bipolar transistor T10 of circuit BG couples the drain of transistor T9 to resistor R61. Transistor T10 has its base connected to the base of transistor T8, and, for example, its collector connected to the drain of transistor T9 and its emitter coupled to resistor R61, for example via a resistor R63 preferably having one terminal connected to transistor T10 and another terminal connected to resistor R61.

Transistors T1, T8, T9, and T10, and resistors R53, R61, R62, and R63 are sized so that the voltage Vbg on terminal 1000 of resistor R55 is temperature-stable, that is constant with temperature. Further, bipolar transistors T8 and T10 are, for example, sized so that the current in transistor T8 is of PTAT type. For example, transistor T10 is implemented by a parallel connection of a plurality of transistors identical to transistor T8, so that the voltage across resistor R63 is of PTAT type.

Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A device comprising:
a first bandgap circuit configured to apply a temperature-stable voltage across a first resistive element so that a first current flows therethrough, and to deliver a second current proportional to absolute temperature;
a second resistive element comprising one or a plurality of MOS transistors in series and each connected as a diode, the second resistive element having a first terminal connected to a node of application of a reference potential and a second terminal coupled to a node of application of a power supply potential;
a second circuit connected to the first circuit and configured to deliver a first copy of the first current and so that the first copy of the first current flows through the second resistive element; and
a third circuit connected to the first circuit and configured to:
deliver a copy of the second current, deliver a first control voltage from the copy of the second current, and apply the first control voltage to a back gate of the transistors of the second resistive element, or
deliver a second copy of the first current and a copy of the second current, supply a first control voltage from a difference between the second copy of the second current and the first copy of the first current, and apply the first control voltage to a back gate of the transistors of the second resistive element.

2. The device of claim 1, wherein the second terminal of the second resistive element is configured to deliver a bias voltage to a variable capacitor.

3. The device of claim 2, wherein the device comprises the variable capacitor;
wherein the variable capacitor is configured to receive a tuning voltage and the bias voltage; and
wherein a difference between the tuning voltage and the bias voltage determines a value of a capacitance of the variable capacitor.

4. The device of claim 3, wherein the device comprises a voltage-controlled oscillator comprising the variable capacitor.

5. The device of claim 4, wherein the device comprises a circuit for delivering the tuning voltage, the circuit comprising, for example, a phase-locked loop.

6. The device of claim 1, wherein the second resistive element is in series with a resistor;
wherein the second terminal of the second resistive element is configured to deliver a first bias voltage to a variable capacitor and is connected to a first terminal of the resistor; and
wherein a second terminal of the resistor is configured to deliver a second bias voltage to the variable capacitor.

7. The device of claim 6, wherein the device comprises the variable capacitor;
wherein the variable capacitor is configured to receive a tuning voltage and the first and second bias voltages; and
wherein a difference between the tuning voltage and the first bias voltage and a difference between the tuning voltage and the second bias voltage determine a value of a capacitance of the variable capacitor.

8. The device of claim 7, wherein the device comprises a voltage-controlled oscillator comprising the variable capacitor.

9. The device of claim 8, wherein the device comprises a circuit for delivering the tuning voltage, the circuit comprising, for example, a phase-locked loop.

10. The device of claim 1, wherein the third circuit comprises a resistor having a first terminal connected to the node of application of the reference potential or to the node of application of the power supply potential, a second terminal of the resistor being configured to deliver the first control voltage and being connected to the back gate of the transistors of the second resistive element.

11. The device of claim 8, wherein the third circuit comprises a smoothing capacitor connected between the back gate of the transistors of the second resistive element and the node of application of the reference potential.

12. The device of claim 1, wherein the transistors of the second resistive element all are N-channel transistors or all are P-channel MOS transistors.

13. The device of claim 1, wherein the transistors of the second resistive element are all implemented on silicon on insulator.

14. The device of claim 1, wherein the third circuit comprises a circuit for adjusting a slope of the first control voltage with temperature.

15. The device of claim 14, wherein the third circuit comprises a resistor having a first terminal connected to the node of application of the reference potential or to the node of application of the power supply potential, a second terminal of the resistor being configured to deliver the first control voltage and being connected to the back gate of the transistors of the second resistive element;
wherein an adjustment circuit comprises one or a plurality of assemblies, each comprising:
a first resistor and a first switch in series between the node of application of the power supply potential and the second terminal of the resistor delivering the first control voltage; and
a second resistor and a second switch in series between the second terminal of the resistor delivering the first control voltage and the node of application of the reference potential, a value of the second resistor of the assembly being identical to a value of the first resistor of the assembly.

16. The device of claim 15, wherein the adjustment circuit comprises a plurality of the assemblies; and
wherein a value of the first resistor is different in each of the assemblies.

17. The device of claim 14, wherein the first control voltage is determined by the difference between the second copy of the first current and the copy of the second current; and
wherein a slope adjustment circuit comprises a fourth circuit configured to deliver the second copy of the first current, and a fifth circuit configured to deliver the second copy of the second current, a gain of the fourth circuit and a gain of the fifth circuit being adjustable in such a way as to allow the adjustment of the slope of the first control voltage with temperature.
